(19) United States
(12) Patent Application Publication
(10) Pub. No.: US 2022/0056061 A1
(43) Pub. Date: Feb. 24, 2022

(54) ORGANOMETALLIC COMPOUNDS

(71) Applicant: UMICORE AG & CO. KG, Hanau-Wolfgang (DE)

(72) Inventors: Susanne HERRITSCH, Marburg (DE); Joerg SUNDERMEYER, Marburg (DE); Andreas RIVAS NASS, Bensheim (DE); Oliver BRIEL, Alzenau (DE); Ralf KARCH, Kleinostheim (DE); Wolf SCHORN, Waldbronn (DE); Annika FREY, Hanau (DE); Angelino DOPPIU, Seligenstadt (DE); Eileen WOERNER, Nidderau (DE)

(73) Assignee: UMICORE AG & CO. KG, Hanau-Wolfgang (DE)

(21) Appl. No.: 17/312,483

(22) PCT Filed: Nov. 28, 2019
(86) PCT No.: PCT/EP2019/082892

§ 371 Date: Jun. 10, 2021

(30) Foreign Application Priority Data
Dec. 12, 2018 (EP) 18212064.2

(51) Int. Cl. C07F 11/00; C23C 16/455; C23C 16/18

(52) U.S. Cl. CPC C07F 11/00; C23C 16/18; C23C 16/45553

(57) ABSTRACT

The invention relates to a two-stage synthesis for the production of bis(tertbutylimido)bis(dialkylamido)tungsten compounds according to the general formula [W(NtBu)₂(NR^{A}R^{B})₂] (I), starting from [W(NtBu)₂(NHtBu)₂]. The invention also relates to compounds according to the general formula [W(NtBu)₂(NR^{A}R^{B})₂] (I), obtainable according to the claimed method, compounds according to general formula [W(NtBu)₂(NR^{A}R^{B})₂] (I), with the exception of [W(NtBu)₂(NMe₂)₂] and [W(NtBu)₂(NEtMe)₂], the use of a compound [W(NtBu)₂(NR^{A}R^{B})₂] (I), and a substrate which, on a surface, has a tungsten layer or a tungsten-containing layer. Defined bis(tertbutylimido)bis(dialkylamido)tungsten compounds of the type [W(NtBu)₂(NR^{A}R^{B})₂] (I) can be produced easily, economically and reproducibly in high purity and good yields by means of the described method. On account of their high purity, the compounds are suitable for producing high-quality substrates which have tungsten layers or tungsten-containing layers.

The invention relates to a method for the production of compounds according to the general formula [W(NtBu)₂(NR^{A}R^{B})₂] which hereinafter are also referred to as bis(tertbutylimido)bis(dialkylamido)tungsten compounds or bis(tertbutylimido)bis(dialkylamido)tungsten complex. R^{A} and R^{B} are independently selected from the group consisting of linear and branched alkyl radicals having 1 to 20 carbon atoms. The subject matter of the invention are also compounds according to the general formula [W(NtBu)₂(NR^{A}R^{B})₂], obtainable according to the claimed method, compounds according to the general formula [W(NtBu)₂(NR^{A}R^{B})₂], with the exception of [W(NtBu)₂(NMe₂)₂] and [W(NtBu)₂(NEtMe)₂], the use of a compound [W(NtBu)₂(NR^{A}R^{B})₂] and a substrate which, on a surface, has a tungsten layer or a tungsten-containing layer.

Tungsten layers and tungsten-containing layers are important inter alia in semiconductor, solar, TFT LCD and flat screen technology. Tungsten nitride layers, for example, constitute good copper diffusion barriers for microelectronic components. Due to its low electrical resistance and its resistance to copper, tungsten nitride constitutes a comparatively promising barrier material. Thin tungsten nitride films can also be used as electrodes for thin-film capacitors and field-effect transistors.

In the semiconductor industry, in particular, the growth of tungsten nitride layers with a low specific resistance and an excellent step coverage is pursued. Vapor deposition methods are typically used to produce such tungsten nitride layers, other tungsten-containing layers, such as, for example, layers or films of WON, WSi, WSiN and WO as well as pure tungsten layers. Most commonly, different ALD methods (atomic layer deposition) and CVD methods (chemical vapor deposition) are used.

Here and hereinafter, the specification of an exact stoichiometry of the depositable tungsten-containing layers or films has been dispensed with. Moreover, the term “layer” is used synonymously with the expression “film” and does not make any statement about the layer thickness or the film thickness.

The deposition of tungsten nitride layers by means of an ALD method was described, for example, in year by 2000 Klaus et al. (J. W. Klaus, S. J. Ferro, S. M. George, J. Electrochem. Soc. 2000, 147, 1175-1181). Based on WF₆ and NH₃, tungsten nitride layers having a good step coverage were obtained. However, the disadvantage of this method is that WF₆ and/or the by-product hydrogen fluoride produced during the process particularly attacks substrates which consist of silicon or contain silicon. In addition, fluorine impurities on the surface of the tungsten nitride layer can negatively influence the adhesion of copper that is desired later.

The bis(alkylimido)bis(dialkylamido)tungsten compound [W(NtBu)₂(NMe₂)₂], for example, is known in the prior art as a halogen-free precursor for the deposition of tungsten nitride layers. In 2003, Becker et al, reported on its synthesis and application as a precursor in an ALD process. (J. S. Becker, S. Suh, S. Wang, R. G. Gordon, Chem. Mater. 2003, 15, 2969-2976)

The synthesis route for preparing [W(NtBu)₂(NMe₂)₂] published by Becker et al. comprises three stages and is used by the authors analogously for the production of [W(NtBu)₂(NMeEt)₂]. In the first step for the production of [W(NtBu)₂(NMeEt₂)₂], commercially available WCl₆ with four equivalents of HN(tBu)(SiMe₃) is reacted in toluene to half an equivalent of mixed-substituted tert-butylamine adduct [W(NtBu)₂Cl₂(NH₂tBu)]2. To isolate and purify this first intermediate, a filtration step for separating (tBu)(Me₃Si)NH₂Cl and unreacted WCl₆ as well as a crystallization step are provided inter alia. The second stage involves the reaction of half an equivalent of [W(NtBu)₂Cl₂(NH₂tBu)]2 with two equivalents of pyridine in diethyl ether In this case the pyridine adduct [W(NtBu)₂Cl₂(py)₂] is obtained with the release of tert-butylamine (tBuNH₂). To isolate this second intermediate, the solvent diethyl ether, tBuNH₂ and excess pyridine must be removed in a vacuum, which is problematic because of the high boiling temperature of pyridine. For the third and last reaction step, the educt lithium dimethylamide (LiNMe₂) must first be prepared in a separate synthesis. This is because the target compound [W(NtBu)₂(NMe₂)₂] is produced by reacting an equivalent of [W(NtBu)₂Cl₂(py)₂] with two equivalents of LiNMe₂ in diethyl ether. This third step is described as very violent and exothermic. Purification of the product [W(NtBu)₂(NMe₂)₂] includes a filtration step for separating the LiCl load produced during the reaction and excess LiNMe₂. Furthermore, two distillations under reduced pressure are provided. The compounds [W(NtBu)₂(NMe₂)₂] and [W(NtBu)₂(NEtMe)₂] are each described as a pale yellow liquid. No indication of the respective overall yield is given in the literature.

A significant disadvantage of the known method for preparing the bis(alkylimido)bis(dialkylamido)tungsten compound [W(NtBu)₂(NMe₂)₂] is the plurality of reaction steps and the effort and time associated with each of the three synthesis steps. Two intermediates are produced and isolated, namely [W(NtBu)₂Cl₂(NH₂tBu)]₂ and [W(NtBu)₂Cl₂(py)₂]. Their isolation and/or purification in each case comprises at least one time and/or labor-intensive step. In addition, the educt LiNMe₂ is to be produced in a separate reaction for the third synthesis stage. A further disadvantage is that, inter alia, the solvents diethyl ether and pyridine, which are in principle capable of coordination, are used. In the third step in particular, the use of diethyl ether as solvent is disadvantageous because the removal of the LiCl load produced as by-product and of the excess LiNMe₂ can consequently be difficult, or at least harder. If lithium ions are present in the reaction mixture, lithium tungstate complex salts can also be formed, which are likewise difficult to separate or cannot be separated at all. With a view to an industrial application of bis(alkylimido)bis(dialkylamido)tungsten compounds and a synthesis thus required on an industrial scale, the third synthesis step in particular is disadvantageous, especially since it is described as very violent and exothermic and is, therefore, at least to be classified as critical for safety reasons.

Moreover, the procedure known in the literature provides a complex purification of the end product [W(NtBu)₂(NMe₂)₂] or [W(NtBu)₂(NMe₂)₂] by means of a filtration step and two distillations. Nevertheless, the products obtained in this way can have not precisely quantifiable salt impurities, in particular lithium impurities. Unlike the product in pure form, its properties can therefore be altered or impaired in an uncontrollable and in some cases irreversible manner. It is unknown whether, with the reaction control described above, yields are obtained which are satisfactory with a view to industrial use of said compound.

On the whole, the synthesis route documented in the literature can be classified as unsatisfactory from ecological and economic perspectives.

The object of the invention is therefore to overcome these and further disadvantages of the prior art and to provide a method by means of which defined bis(alkylimido)bis(dialkylamido)tungsten compounds can be produced easily, efficiently, economically and reproducibly in high purity and good yields. In particular, the purity of the bis(alkylimido)bis(dialkylamido)tungsten compounds, which can be produced by the method, should satisfy the requirements for precursors for the production of high-quality substrates which have tungsten layers or tungsten-containing layers. The method is to be characterized by the fact that it can also be carried out on an industrial scale with a comparable yield and purity of the target compounds. In addition, novel bis(alkylimido)bis(dialkylamido)tungsten compounds are to be provided. Furthermore, a substrate is to be provided which, on a surface, has a tungsten layer or a tungsten-containing layer, which can be produced using a bis(alkylimido)bis(dialkylamido)tungsten compound obtainable or obtained by the claimed method or using one of the novel bis(alkylimido)bis(dialkylamido)tungsten compounds.

The main features of the invention are set forth in claim 1 or any one of claims 22 through 33. The embodiments are the subject of claims 2 through 21.

The object is achieved by

a method for the production of bis(alkylimido)bis(dialkylamido)tungsten compounds
according to the general formula

[W(NtBu)₂(NR^{A}R^{B})₂] (I),

wherein
R^{A} and R^{B} are independently selected from the group consisting of linear and branched alkyl radicals having 1 to 20 carbon atoms,
comprising the following steps:
a) provision of [W(NtBu)₂(NHtBu)₂]
and
b) reaction of [W(NtBu)₂(NHtBu)₂] from step a) with an amine according to the general formula HNR^{A}R^{B} in a solvent M_{U},
wherein
R^{A} and R^{B} are independently selected from the group consisting of linear and branched alkyl radicals having 1 to 20 carbon atoms,
   and
a molar ratio [W(NtBu)₂(NHtBu)₂]:HNR^{A}R^{B} is <1:2.

In this case, the general formula I includes both the monomers and any oligomers.

The alkyl radicals R^{A} and R^{B} may also be substituted, for example be partially or fully halogenated.

The solvent M_{U} may also be a solvent mixture comprising two or more solvents.

The claimed method advantageously allows the production of the target compounds [W(NtBu)₂(NR^{A}R^{B})₂] (I) in a simple two-stage synthesis.

By reacting one molar equivalent of the compound [W(NtBu)₂(NHtBu)₂] provided in step a) with an excess of the amine HNR^{A}R^{B} in the solvent M_{U}, the respective bis(tertbutylimido)bis(dialkylamido)tungsten complex is obtained in step b). Here, excess means that more than two molar equivalents HNR^{A}R^{B}, which are technically required for the production of [W(NtBu)₂(NR^{A}R^{B})₂] (I), are provided. The molar ratio [W(NtBu)₂(NHtBu)₂]:HNR^{A}R^{B} is thus less than 1:2, i.e. less than 0.5. The level of the excess of HNR^{A} R^{B} to be selected depends, in particular, on the reactivity of the secondary amine used respectively in step b) as educt, in particular taking into account the reaction parameters otherwise selected, such as for example the solvent or solvent mixture.

In the claimed two-stage synthesis, after step b) has been carried out only the desired bis(tertbutylimido)bis(dialkylamido)tungsten compound of the type [W(NtBu)₂(NR^{A}R^{B})₂] (I) and the defined, comparatively easily separable by-product tBuNH₂ and amine HNR^{A}R^{B} that is unreacted, i.e. used in excess, are present. The tBuNH₂ obtained in step b) is comparatively highly volatile and can thus be quantitatively removed in a simple manner, namely by applying a slight negative pressure to an interior of the respective reaction vessel. The same generally applies to the HNR^{A}R^{B} used in excess in step b), in particular to very highly volatile amines, such as, for example, HNMe₂.

Furthermore, it is advantageous that—due to the absence of lithium compounds, particularly LiCl—no undefinable by-products are formed, for example lithium tungstate complex salts, which can only be separated with difficulty or not at all. The respective target compound of the type [W(NtBu)₂(NR^{A}R^{B})₂] (I) in solution can be reacted directly with one or more reactants. Alternatively, the compound of the type [W(NtBu)₂(NR^{A}R^{B})₂] (I) can be isolated easily, for example, by removing all volatile constituents. Furthermore, the isolated compound—as per an NMR spectroscopic examination—has neither amine impurities nor residues of the solvent or solvent mixture used. The respective target compound can thus be used and/or stored after isolation without further purification. The reproducible yield is satisfactory for [W(NtBu)₂(NMe₂)₂], for example—even when upscaling to an industrial scale.

As a whole, the method claimed overcomes the disadvantages of the prior art. In particular, no difficult-to-separate salt loads are obtained, such as, for example, LiCl in diethyl ether. Potentially coordinating solvents, such as pyridine and diethyl ether, are dispensed with completely. The method is characterized by a particularly simple and economical method because it is a simple two-stage synthesis. In addition, few process steps that are easily accomplished in terms of preparation are necessary. Only educts that are commercially easily available, synthetically relatively easily accessible and relatively economical are used, Only by-products that are definable and separable easily and quantitatively are formed. In particular, non-separable lithium tungstate complex salts are not formed. Therefore, compounds of the type [W(NtBu)₂(NR^{A}R^{B})₂] (I), such as, for example, bis(tertbutylimido)bis(dimethylamido)tungsten, are obtained reproducibly in high purity, even without any further distillative and/or sublimative purification. However, transcondensation and/or distillation and/or sublimative purification may be provided, for example. The bis(tertbutylimido)bis(dialkylamido)tungsten compounds obtainable by the claimed method meet the purity requirements for precursors for the production of high-quality substrates which have tungsten layers or tungsten-containing layers. In particular, the compounds of the type [W(NtBu)₂(NR^{A}R^{B})₂] (I), which can be produced by the claimed method, do not inherently have lithium impurities, namely due to the omission of educts, such as, for example, lithium dimethylamide. In addition, the method can also be carried out on an industrial scale, wherein comparable yields and purities of the target compounds are achieved. The method claimed saves time, energy and costs in comparison. On the whole, it can be classed as comparatively more (atom-)economical and more ecological.

In one embodiment of the claimed method for the production of bis(tertbutylimido)bis(dialkylamido)tungsten compounds according to the general formula [W(NtBu)₂(NR^{A}R^{B})₂] (I), R^{A} and R^{B} are independently selected from the group consisting of Me, Et, nPr, Pr, nBu, tBu, sBu, iBu, CH₂sBu, CH₂iBu, CH(Me)(iPr), CH(Me)(nPr), CH(Et)₂, C(Me)₂(Et), C₆H₁₁, CH₂C₆H₅ and C₆H₅.

In a further embodiment of the claimed method, the provision of [W(NtBu)₂(NHtBu)₂] in step a) a reaction of WCl₆ with tBuNH₂ in the presence of an auxiliary base in an aprotic solvent M_{A}. Here, a molar ratio WCl₆:tBuNH₂ is ≤1:4.

The inexpensive, commercially available WCl₆ is used as educt. On this basis, a production of the intermediate [W(NtBu)₂(NHtBu)₂] is accomplished by reaction with at least four molar equivalents of tBuNH₂ in the aprotic solvent M_{A}. The hydrogen chloride obtained thereby as a single by-product is absorbed by means of an auxiliary base contained in the reaction mixture.

In principle, any compound which, under the reaction conditions selected in each case, is capable of quantitatively absorbing the hydrogen chloride produced during the respective reaction, can be used as an auxiliary base. The auxiliary base must be characterized, in particular, by the fact that it does not affect the pH of the reaction mixture and the water content of the reaction medium and, with respect to the educts WCl₆ and tBuNH₂ as well as to the desired intermediate [W(NtBu)₂(NHtBu)₂], does not act as a reactant. In addition, any excess of the auxiliary base used must be easily quantitatively removable from the reaction mixture and the product obtained by the reaction of the auxiliary base with the hydrogen chloride must likewise be easily quantitatively separable. A molar ratio WCl₆:auxiliary base is selected such that at least six molar equivalents of hydrogen chloride can be absorbed.

In the simplest case, tBuNH₂ is both reactant or educt and auxiliary base. Then, the hydrogen chloride formed during the reaction reacts with the amine tBuNH₂ used in excess to form tBuNH₃Cl. Excess in this context means that per molar equivalent of WCl₆ at least ten—instead of the four that are technically required for obtaining [W(NtBu)₂(NHtBu)₂]—equivalents of tBuNH₂ can be used. The molar ratio WCl₆:tBuNH₂ is in this simplest case therefore ≤1:10. Any possibly unreacted tBuNH₂ can be removed simply by applying a negative pressure to an interior of the respective reaction vessel. Alternatively, it can be provided for the auxiliary base to only comprise the amine tBuNH₂, i.e. part of the auxiliary base tBuNH₂ is replaced by another auxiliary base. The overall molar ratio of Was tBuNH₂ provided in the reaction mixture is then <1:4 and >1:10, i.e. <0.25 and >0.10.

The term reaction vessel in the context of the present invention is not limited to a volume, a material composition, equipment or a form.

After carrying out the reaction of WCl₆ with tBuNH₂ in the presence of an auxiliary base, only the desired intermediate [W(NtBu)₂(NHtBu)₂] and defined, comparatively easily separable by-products, typically an ammonium salt, for example tBuNH₃Cl, and potentially tBuNH₂ that is unreacted, i.e. used in excess, are present. Any tBuNH₂ still present in the reaction mixture can be removed easily by applying a negative pressure to an interior of the respective reaction vessel. The relatively easy separability of the precipitated ammonium salt, for example tBuNH₃Cl, can also be explained by the advantageous selection of the aprotic solvent M_{A}.

One embodiment of the method provides that the aprotic solvent M_{A} is selected from the group consisting of hydrocarbons, benzene and benzene derivatives. The first solvent is for example selected from the group consisting of n-pentane, n-hexane, n-heptane, n-octane, n-nonane, n-decane, n-undecane, n-dodecane, cyclopentane, cyclohexane, cycloheptane, 1-pentene, 1-hexene, 1-heptene, 1-octene, 1-nonene, 1-decene, 1-undecene, 1-dodecene, cyclohexene, benzene, toluene, xylene and isomers thereof. The aprotic solvent M_{A} is preferably n-hexane, i-hexane or n-heptane or a mixture comprising at least one of said solvents. Advantageously, the aforementioned solvents, in particular benzene and toluene, can be completely recycled without losses. This has a positive effect on the environmental balance of the method.

In a further variant of the claimed method, in step a) the reaction of WCl₆ with tBuNH₂ in the presence of the auxiliary base, in the aprotic solvent M_{A} comprises the following steps of:

i) providing a solution of tBuNH₂ in the aprotic solvent M_{A},
ii) adding the auxiliary base,
iii) adding WCl₆,
wherein during the addition and/or after the addition of WCl₆, a reaction of WCl₆ with tBuNH₂ takes place.

The aprotic solvent M_{A} may also be a mixture of solvents.

Preference is given to the auxiliary base tBuNH₂, wherein a molar ratio WCl₆:auxiliary base tBuNH₂ is ≤1:6. Therefore, together with the tertbutylamine required as reactant for the production of [W(NtBu)₂(NR^{A}R^{B})₂] (I), a molar ratio WCl₆:tBuNH₂ is ≤1:10. If tBuNH₂ functions both as educt and as auxiliary base, the process is particularly simple. On the one hand, the number of chemicals required is reduced. On the other hand, step i), namely the provision of a solution of tBuNH₂ in the aprotic solvent M_{A}, and step ii), namely the addition of the auxiliary base, take place in a single step.

If, in another embodiment of the claimed method, an auxiliary base other than the amine tBuNH₂ is used, it can be provided that this auxiliary base is added in the separate step ii). The auxiliary base is added in bulk, i.e, generally as a solid or liquid, or as a suspension or solution in a solvent SR. The solvent S_{H} is identical or miscible with the aprotic solvent M_{A}.

In the context of the present invention, two solvents are referred to as miscible if they are miscible at least during the respective reaction, that is, are not present as two phases.

In one embodiment of the claimed method, it is provided that in step iii) Was is suspended in a solvent S_{W} or added as a solid. The solvent S_{W} is identical to or miscible with the aprotic solvent M_{A}. The addition of WCl₆ as a suspension in the solvent S_{W} can, as a function of the other reaction parameters, be advantageous for better control of the course of the reaction or of the exothermic reaction. The addition is then effected, for example, using a dosing device, in particular by adding a drop at a time or injecting. If WCl₆ is added as a solid, a funnel or a funnel-like device, for example, is provided for the addition. In the alternative or in addition, a shut-off valve and/or a stop valve can be provided in a supply line of the respective reaction vessel, irrespective of the form in which WCl₆ is added.

In yet another embodiment of the claimed method, in step i) WCl₆ is provided or added as a suspension in the aprotic solvent M_{A}. If tBuNH₂ is provided as auxiliary base, step ii) and step iii) take place in a single step. In this case, tBuNH₂ is added as a solution in a solvent SR or as a liquid, that is, without addition of a solvent, in each case, for example, by adding a drop at a time or injecting. The solvent S_{R} is identical or miscible with the aprotic solvent M_{A}. If an auxiliary base other than tBuNH₂ is provided, this auxiliary base is added in the separate step ii). The auxiliary base is added in substance, i.e. generally as a solid or liquid, or as a suspension or solution in a solvent S_{B}. The educt tBuNH₂ is then added in step iii) as a solvent S_{P} or as a liquid, that is, without addition of a solvent, in each case, for example, by adding a drop at a time or injecting. In this case, the solvents S_{B} and S_{P} are each identical to or miscible with the aprotic solvent M_{A}.

Depending on the choice of aprotic solvent or solvent mixture M_{A} and the other reaction conditions, such as, for example, addition form of WCl₆, that is, as a substance or as a suspension, rate of addition of WCl₆, stirring speed, internal temperature of the respective reaction vessel, the WCl₆ reacts with tBuNH₂ in the presence of the auxiliary base already during the addition and/or after the addition of WCl₆.

In another variant of the claimed method, the reaction of WCl₆ with tBuNH₂ in the presence of the auxiliary base, in particular tBuNH₂, in the aprotic solvent M_{A} is carried out at a temperature T_{U}, wherein the temperature T_{U} is between −30° C. and 100° C.

Temperature T_{U} means the internal temperature T_{U} of the respective reaction vessel.

Owing to the exothermicity of the reaction, it may be advantageous to select comparatively low rates for the addition of WCl₆ and/or the temperature T_{U}. In the alternative or in addition, it may be provided that a suspension of

WCl₆ is added in an aprotic solvent or solvent mixture. The respective procedure is to be selected taking into account the other reaction parameters, such as, for example, the tBuNH₂ concentration (educt) and the solvent or solvent mixture.

In a further embodiment of the method, the temperature To of the during the reaction of WCl₆ with tBuNH₂ in the presence of the auxiliary base, especially tBuNH₂, is between −20° C. and 80° C. In yet another embodiment of the method, the temperature T_{U} during the reaction of WCl₆ with tBuNH₂ in the presence of the auxiliary base, especially tBuNH₂, is between −10° C. and 50° C.

An internal temperature of the respective reaction vessel can be determined by means of a temperature sensor or a plurality of temperature sensors for one or more regions of the reaction vessel. At least one temperature sensor is provided for determining the temperature T_{U}, which generally corresponds to an average temperature To of the reaction mixture.

In a further variant of the method, the temperature T_{U} is regulated and/or controlled using a heat transfer medium W_{U}. For this purpose, a cryostat can be used, for example, which contains a heat transfer medium, which ideally can function both as a coolant and as a heating medium. Through the use of the heat transfer medium W_{U}, deviations of the temperature T_{U} from a set value T_{S1} defined for the reaction of WCl₆ with tBuNH₂ in the presence of the auxiliary base, in particular tBuNH₂, can be absorbed or compensated for as much as possible. Typical device deviations render it hardly possible to realize a constant temperature T_{U}. Through the use of the heat transfer medium W_{U}, however, the reaction of WCl₆ with tBuNH₂ in the presence of the auxiliary base, especially tBuNH₂, can take place at least within a preselected temperature range or within a plurality of preselected temperature ranges. For example, depending on the remaining reaction parameters, it may be advantageous to provide a temperature program for even better control of the course of the reaction or the exothermic reaction. In this case, for example, a lower temperature or a lower temperature range can be selected during a first phase of the addition of WCl₆ than in a second phase of the addition of WCl₆. It is also possible to provide more than two phases of the addition and thus more than two preselected temperatures or temperature ranges. Depending on the choice of other reaction conditions, such as, for example, the tBuNH₂ concentration (educt) and the solvent or solvent mixture, it may be favorable during the addition and/or after the addition of WCl₆ to increase the temperature T_{U} using the heat transfer medium W_{U}. This may make it possible to ensure that the reaction of WCl₆ with tBuNH₂ in the presence of the auxiliary base, especially tBuNH₂, is carried out quantitatively.

If the provision of [W(NtBu)₂(NHtBu)₂] in step a) comprises a reaction of WCl₆ with tBuNH₂ in the presence of an auxiliary base in an aprotic solvent M_{A}, a further variant of the claimed method provides for a filtration step to be performed prior to the reaction of [W(NtBu)₂(NHtBu)₂] in step b). The filtration step or decanting takes place, in particular, to separate the ammonium salt, especially tBuNH₃Cl, produced during the reaction of WCl₆ with tBuNH₂ in the presence of an auxiliary base, especially tBuNH₂. If, for example n-hexane, i-hexane and/or n-heptane are used as solvent, the ammonium salt, for example tBuNH₃Cl, is precipitated quantitatively, while the intermediate [W(NtBu)₂(NHtBu)₂] remains in solution. Within the context of isolating the intermediate [W(NtBu)₂(NHtBu)₂], several filtration steps can also be provided, optionally also one or more filtrations over a cleaning medium, e.g. activated carbon or silica, e.g. Celite®. The filter cake comprising the ammonium salt load may be washed with a small amount of a volatile solvent to extract any product possibly contained in the ammonium salt load. Contamination of the bis(tertbutylimido)bis(dialkylamido)tungsten complex to be produced in step b) by the resulting ammonium salt load, for example tBuNH₃Cl, is thus advantageously avoided.

Another variant of the method provides for [W(NtBu)₂(NHtBu)₂] to be isolated prior to the reaction of [W(NtBu)₂(NHtBu)₂] in step b). Isolating may comprise removing all volatile constituents, that is, the solvent or solvent mixture M_{A} and any tBuNH₂ that is unreacted i.e. used in excess. In a further embodiment of the claimed method, isolating [W(NtBu)₂(NHtBu)₂] comprises applying a negative pressure pw to an interior of the reaction vessel. The negative pressure p_{W}, as a function of the other reaction conditions, in particular as a function of the solvent, is, for example, 10⁻³ to 10¹ mbar. This makes it possible, for example, to completely or almost completely separate and recycle the solvent or solvent mixture from step a). This is particularly advantageous from an economical and ecological point of view.

Isolating may comprise further method steps, such as, for example, the reduction of the mother liquor volume, i.e. concentration, for example by means of “bulb-to-bulb”, the addition of a solvent and/or a solvent exchange to precipitate the product from the mother liquor and/or to remove impurities and/or educts, washing and drying of the product. Furthermore, it may be provided that isolation comprises distillation and/or sublimation and/or crystallization and/or recrystallization.

In principle, no purification is required for a later reaction of [W(NtBu)₂(NHtBu)₂], in particular according to step b) of the method claimed here. If purification is still desired and/or necessary, the isolation may comprise distillation and/or sublimation and/or crystallization and/or recrystallization. The sublimation of [W(NtBu)₂(NHtBu)₂] can be carried out comparatively easily and quickly. In addition, as a result of the sublimation of [W(NtBu)₂(NHtBu)₂], a significant increase in the yield can advantageously be achieved, unlike in the recrystallization from toluene described in the literature (see embodiment 1).

This isolated and optionally purified compound [W(NtBu)₂(NHtBu)₂] can also be stored for later use.

In a further embodiment of the claimed method, in step b) the molar ratio [W(NtBu)₂(NHtBu)₂] HNR^{A}R^{B} is ≤1:4. Even with a molar ratio of precisely 1:4, i.e. 0.25, a comparatively great excess of the amine is used HNR^{A}R^{B}, namely twice as many molar equivalents of this educt than are technically required. The level of the excess of HNR^{A} R^{B} to be selected in individual cases depends, in particular, on the reactivity of the secondary amine used respectively in step b) as educt, in particular taking into account the otherwise selected reaction parameters, such as, for example, the solvent or solvent mixture.

In another embodiment, the solvent M_{U} comprises an aprotic solvent. Another embodiment of the claimed method provides for the solvent M_{U} to be miscible with or identical to the aprotic solvent M_{A}. In this context, the term “identical” has two different meanings, as can be inferred from the explanations in the following paragraph.

After completion of step a), the present reaction mixture can, for example, be subjected to a filtration step in order to separate off the ammonium salt, for example tBuNH₃Cl, which is produced as a by-product. For this purpose, the filtrate containing the raw product [W(NtBu)₂(NHtBu)₂] from step a), can, for example, be collected in another vessel and, after separation of the ammonium salt, e.g. tBuNH₃Cl, be transferred into the respective reaction vessel again. This can take place, for example, by means of a pumping operation. In this case, the solvent M_{U} comprises the aprotic solvent M_{A} or, if no further solvent is added, is identical thereto. It can, furthermore, be provided for the aprotic solvent or solvent mixture M_{A} to be removed by applying a negative pressure to an interior of the respective reaction vessel, and to not be returned. This is necessary, for example, if, for the reaction according to step b), a solvent M_{U} is preferred, which is different from the aprotic solvent M_{A}. In the event that the raw product [W(NtBu)₂(NHtBu)₂], after removal of the aprotic solvent M_{A}, potentially still has residues of said solvent, it is advantageous for the further reaction according to step b) if the solvent M_{U} is miscible with the solvent M_{A}. The term “miscible” has already been defined above. If the raw product from step a) was isolated intermediately, optionally purified and stored, it can, for the reaction according to step b), depending on the selection of the other reaction conditions, also be dissolved in a solvent M_{U} which is identical to the aprotic solvent M_{A}. If, for example, n-hexane was used as aprotic solvent M_{A}, n-hexane can, in turn, be used as solvent M_{U}, wherein the latter may optionally, but does not have to, be recycled from the process.

In a variant of the claimed method, the aprotic solvent comprising the solvent M_{U}, is selected from the group consisting of hydrocarbons, benzene and benzene derivatives. For example, the aprotic solvent comprising the solvent M_{U} is selected from the group consisting of n-pentane, n-hexane, n-heptane, n-octane, n-nonane, n-decane, n-undecane, n-dodecane, cyclopentane, cyclohexane, cycloheptane, 1-pentene, 1-hexene, 1-heptene, 1-octene, 1-nonene, 1-decene, 1-undecene, 1-dodecene, cyclohexene, benzene, toluene, xylene and isomers thereof. Preference is given to n-hexane, i-hexane and n-heptane and also to solvent mixtures comprising at least one of these solvents.

Yet another embodiment of the claimed method provides for the solvent M_{U} to comprise a reactive solvent. In the context of the present invention, the term “reactive solvent” means a solvent which is not chemically inert. Under the respective reaction conditions, the reactive solvent can react with a potential reactant, for example with an educt and/or a product. The type and extent of the reactivity of the reactive solvent are dependent on the concentration of the reactive solvent present in the respective reaction mixture, the potential reactants, the concentration and reactivity of the potential reactants present in the respective reaction mixture and the other reaction conditions selected in each case.

In a further variant of the claimed method, the reactive solvent comprises the amine HNR^{A}R^{B}. In another embodiment of the claimed method, it is provided for the solvent M_{U} to constitute a solvent mixture comprising the amine HNR^{A}R^{B} as the reactive solvent and at least one aprotic solvent. Here, the at least one aprotic solvent is selected from the group consisting of n-pentane, n-hexane, n-heptane, n-octane, n-nonane, n-decane, n-undecane, n-dodecane, cyclopentane, cyclohexane, cycloheptane, 1-pentene, 1-hexene, 1-heptene, 1-octene, 1-nonene, 1-decene, 1-undecene, 1-dodecene, cyclohexene, benzene, toluene, xylene and isomers thereof. Decisive for the selection of the aprotic solvent is that the amine HNR^{A}R^{B} and the aprotic solvent or solvent mixture are miscible, that is, are miscible at least during the reaction according to step b), that is to say, are not present as two phases.

A further embodiment of the claimed method provides that the molar ratio [W(NtBu)₂(NHtBu)₂] HNR^{A} R^{B} is between 1:200 and 1:10,000.

In yet another embodiment, the amine HNR^{A}R^{B} itself is the reactive solvent. Then, the reaction of [W(NtBu)₂(NHtBu)₂] is carried out with HNR^{A}R^{B} for example, in the amine HNR^{A}R^{B} as educt or reactant, and the only solvent. At the same time, it is provided that the portion of the amine HNR^{A}R^{B} used as solvent is recycled.

In another variant of the claimed method, step b) is carried out at a temperature T_{R} and/or a pressure p_{R} of the respective reaction vessel.

Temperature T_{R} means the internal temperature T_{R} of the respective reaction vessel and pressure p_{R} means the internal pressure p_{R} of the respective reaction vessel.

At the temperature TR and/or the pressure p_{R}, at least a portion of a molar fraction of the amine NHR^{A}R^{B} is present in liquid or dissolved form. In particular, it is provided that the at least one portion of the total molar fraction of the amine NHR^{A}R^{B} used corresponds to the molar fraction of the amine NHR^{A}R^{B} provided as educt, so that the reaction in step b) can proceed to completion. The temperature T_{R} and the pressure p_{R} are to be selected as a function of the amine NHR^{A}R^{B} selected and of the other reaction conditions, e.g. selection of the solvent. The embodiment described here of the claimed method is provided, for example, when the amine NHR^{A}R^{B} used has a comparatively low boiling point, such as, for example, dimethylamine. It is then advantageous for the implementation of step b), by adjusting the temperature T_{R} and the pressure p_{R}, in particular lowering the temperature T_{R} or increasing the pressure p_{R}, to transfer the respective amine into the liquid state and/or to hold it in this state for a certain time. Furthermore, the variant of the claimed method described here is advantageously provided when the amine NHR^{A}R^{B} used both as educt and as reactive solvent is a solid or is present as a solid under the otherwise selected reaction conditions. In addition, this variant of the claimed method is advantageous if the amine NHR^{A}R^{B} used exclusively as reactant is not miscible with, or soluble in, the in particular aprotic solvent M_{U} under the otherwise selected reaction conditions.

In a further embodiment of the claimed method, in step b) the reaction of [W(NtBu)₂(NHtBu)₂] from step a) with the amine HNR^{A}R^{B} in the solvent M_{U} comprises the following steps of:

i) providing [W(NtBu)₂(NHtBu)₂]
as a solid
   or
as a solution or suspension in the solvent M_{U},
   and
   ii) adding the amine HNR^{A}R^{B},
   wherein, during and/or after the addition of the amine HNR^{A}R^{B}, a reaction of [W(NtBu)₂(NHtBu)₂] with the amine HNR^{A}R^{B} takes place.

The solvent M_{U} can also be a solvent mixture, i.e. comprise two or more solvents.

In one embodiment of the method, in step b) ii) the amine HNR^{A}R^{B} is added to the compound [W(NtBu)₂(NHtBu)₂] provided in step b) i)
as a gas or liquid
   or
dissolved in the solvent M_{U}.

A variant of the method provides that in step b) ii) the amine HNR^{A}R^{B} is added using a dosing device. The addition can be effected, for example, by adding a drop at a time or injecting. In the alternative or in addition, a shut-off valve and/or a stop valve can be provided in a supply line of the respective reaction vessel. The addition of the amine HNR^{A}R^{B} as solution in the, especially aprotic, solvent M_{U} can, as a function of the other reaction parameters, be advantageous for better control of the course of the reaction or of the exothermic reaction.

Another variant of the method provides that a temperature T_{C} is between −60° C. and 50° C. during the addition and/or after the addition of the amine HNR^{A}R^{B}.

Temperature T_{C} means the internal temperature T_{C} of the respective reaction vessel.

In a further variant of the method, the temperature T_{C} is between −40° C. and 30° C. during the addition and/or after the addition of the amine HNR^{A}R^{B}. In yet another embodiment of the method, the temperature T_{C} during the addition and/or after the addition of the amine HNR^{A}R^{B} is between −30° C. and 20° C. At least one temperature sensor is provided for determining the temperature T_{C}, which generally corresponds to an average temperature T_{D2} of the reaction mixture. The temperature sensor may be identical to the one for determining the temperature T_{U}.

In a further embodiment of the method, the temperature T_{C} is regulated and/or controlled using a heat transfer medium W_{C}. For this purpose, a cryostat can be used, for example, which contains a heat transfer medium, which ideally can function both as a coolant and as a heating medium. Through the use of the heat transfer medium W_{C}, deviations of the temperature T_{U} from a set value T_{S2} defined for the period during the addition and/or after the addition of the amine HNR^{A}R^{B} can be absorbed or compensated for as much as possible. Typical device deviations render it hardly possible to realize a constant temperature T_{C}. Through the use of the heat transfer medium W_{U}, however, the reaction of the [W(NtBu)₂(NHtBu)₂] provided in step a) with the amine HNR^{A}R^{B} can at least be carried out within a preselected temperature range or within a plurality of preselected temperature ranges. For example, depending on the remaining reaction parameters, it may be advantageous to provide a temperature program or a temperature profile for even better control of the course of the reaction or the exothermic reaction. In this case, for example, a lower temperature or a lower temperature range can be selected during a first phase of the addition of the amine HNR^{A}R^{B} than in a second phase of the addition of the amine HNR^{A}R^{B}. It is also possible to provide more than two phases of the addition and thus more than two preselected temperatures or temperature ranges. After the addition, one or more phases can likewise be provided for incrementally increasing the temperature T_{C}. Overall, a better control of the exothermic reaction or the course of the reaction is achieved by such a temperature program or temperature profile. In this way, the non-specific side reactions and/or degradation of the respective product [W(NtBu)₂(NR^{A}R^{B})₂] (I) can be prevented or at least reduced.

In yet another variant of the claimed method, [W(NtBu)₂(NR^{A}R^{B})₂] (I) is isolated after step b).

If the bis(tertbutylimido)bis(dialkylamido)tungsten compound according to the general formula [W(NtBu)₂(NR^{A}R^{B})₂] (I), in solution in each case, is not to be further reacted directly but instead isolated and then stored and/or used further, its isolation may comprise one or more steps.

In a variant of the method, the isolation of [W(NtBu)₂(NR^{A}R^{B})₂] (I) comprises applying a negative pressure pₓ to an interior of the respective reaction vessel. The negative pressure pₓ, as a function of the other reaction conditions, in particular as a function of the solvent, is for example, 10⁻³ to 10¹ mbar. This makes it possible, for example, to completely or almost completely separate and recycle the solvent or solvent mixture from step b). This is particularly advantageous from an economical and ecological point of view. By applying such a low negative pressure, tBuNH₂ released during the reaction and, generally, unreacted amine HNR^{A}R^{B} are also removed. In order to remove the latter quantitatively, a greater negative pressure, depending on the amine HNR^{A}R^{B}, may optionally be selected.

In this way, that is, by applying such a low negative pressure, when [W(NtBu)₂(NMe₂)₂] was isolated, dimethylamine, which is unreacted or used as solvent, and tertbutylamine released during the reaction in step b) were removed easily and quantitatively. Further purification of the compound remaining in the respective reaction vessel [W(NtBu)₂(NMe₂)₂], by transcondensation or distillation for example, was not required, according to NMR spectroscopic analysis. This is because extraneous signals by impurities, by-products or decomposition products were not observed in the ¹H-NMR or in the ¹³C-NMR spectrum of [W(NtBu)₂(NMe₂)₂].

The isolation of [W(NtBu)₂(NR^{A}R^{B})₂] (I) may also comprise one or more of the following method steps: the reduction in the volume of the mother liquor, i.e. concentration, for example by means of “bulb-to-bulb”, the addition of a solvent and/or a solvent exchange, in order to achieve precipitation of the product from the mother liquor and/or to remove impurities and/or educts, washing and drying of the product. Furthermore, it can be provided that the isolation comprises distillation and/or sublimation and/or recrystallization.

Generally, no purification is necessary for a later reaction or use of the product [W(NtBu)₂(NR^{A}R^{B})₂] (I) after its isolation. However, it is possible, for example, to provide transcondensation and/or distillation and/or sublimative purification.

With the claimed method for the production of bis(tertbutylimido)bis(dialkylamido)tungsten compounds according to the general formula [W(NtBu)₂(NR^{A}R^{B})₂] (I), the disadvantages of the prior art are overcome. In particular, the compounds obtainable by the claimed method are inherently free of lithium impurities, due namely to the absence of lithium-containing educts, such as, for example, lithium dimethylamide. They are, therefore, particularly suitable as precursors for the deposition of tungsten layers or tungsten-containing layers.

The object is further achieved by bis(tertbutylimido)bis(dialkylamido)tungsten compounds according to the general formula

[W(NtBu)₂(NR^{A}R^{B})₂] (I),

wherein
R^{A} and R^{B} are independently selected from the group consisting of linear and branched alkyl radicals having 1 to 20 carbon atoms, obtainable by a method for the production of bis(tertbutylimido)bis(dialkylamido)tungsten compounds according to one of the exemplary embodiments described above.

The bis(tertbutylimido)bis(dialkylamido)tungsten compounds according to the general formula [W(NtBu)₂(NR^{A}R^{B})₂] (I) can advantageously be produced particularly easily and economically in a two-stage synthesis. The compounds of the type [W(NtBu)₂(NR^{A}R^{B})₂] (I) are reproducible even without further distillative and/or sublimative purification producible in high purity. However, it is possible, for example, to provide transcondensation and/or distillation and/or sublimative purification. Bis(tertbutylimido)bis(dialkylamido)tungsten compounds according to the general formula [W(NtBu)₂(NR^{A}R^{B})₂] (I) meet the purity requirements of precursors for the production of high-quality substrates which have tungsten layers or tungsten-containing layers. In particular, they can be produced without the use of lithium-containing educts, such as lithium dimethylamide, and are thus obtainable free from lithium impurities. In addition, the bis(tertbutylimido)bis(dialkylamido) tungsten compounds can also be produced on an industrial scale, wherein comparable yields and purity of the target compounds are achieved. The reproducible yield is satisfactory for [W(NtBu)₂(NMe₂)₂], for example—even when upscaling to an industrial scale.

Bis(tertbutylimido)bis(dialkylamido)tungsten compounds according to the general formula I, such as, for example, [W(NtBu)₂(NMe₂)₂] and [W(NtBu)₂(NMe)₂], are known. Compounds of the type [W(NtBu)₂(NR^{A}R^{B})₂], obtainable by a method for the production of bis(tertbutylimido)bis(dialkylamido)tungsten compounds according to one of the exemplary embodiments described above, differ significantly in their properties from those that can be produced by a method of the prior art. The isolated target compounds thus have, without complex purification, at least as high a purity as compounds of the type [W(NtBu)₂(NR^{A}R^{B})₂], which were produced according to the method of the prior art and purified by means of two fractionating distillations. In particular, they are inherently free from lithium impurities, namely due to the omission of lithium-containing educts, such as, for example, lithium dimethylamide, during their production. If the educt [W(NtBu)₂(NHtBu)₂] is first produced by reacting Was with tBuNH₂ in the presence of an auxiliary base, in steps a) and b) overall—apart from the respectively desired target compound—only defined, comparatively easily separable by-products are produced, typically an ammonium salt, for example tBuNH₃Cl, and tBuNH₂. Furthermore, excess, i.e. unreacted, amine HNR^{A}R^{B} may need to be removed. The relatively easy separability of the ammonium salt precipitating in step a) can also be explained by the advantageous selection of an aprotic solvent. If, for example n-hexane, i-hexane and/or n-heptane are used as solvent, the ammonium salt, for example tBuNH₃Cl, is precipitated quantitatively, while the target compound, for example [W(NtBu)₂(NMe₂)₂] remains in solution. Contamination of the respective bis(tertbutylimido)bis(dialkylamido)tungsten complex by the resulting ammonium salt load, for example tBuNH₃Cl, is thus advantageously avoided. The tBuNH₂ obtained in step b) of the claimed method is comparatively highly volatile and can thus also be easily quantitatively removed, namely by applying a slight negative pressure to an interior of the respective reaction vessel. The same generally applies to the HNR^{A}R^{B} used in excess in step b), in particular to very highly volatile amines, such as, for example, HNMe₂. Furthermore, it is advantageous that undefinable byproducts are not formed, for example lithium tungstate complex salts, which can only be separated with difficulty or not at all. It is particularly advantageous that the ammonium salt, for example tBuNH₃Cl, produced in step a) can be removed easily and quantitatively by a filtration step before the reaction in step b). The compound of the type [W(NtBu)₂(NR^{A}R^{B})₂] (I), which is in solution in each case after step b) is carried out, may be isolated, for example, simply by removing all volatile constituents. Furthermore, the isolated compound has neither amine impurities nor residues of the solvent or solvent mixture used. The respective target compound can thus be used and/or stored after isolation without further purification.

In one embodiment of the bis(tertbutylimido)bis(dialkylamido)tungsten compounds according to the general formula [W(NtBu)₂(NR^{A}R^{B})₂] (I), obtainable by a method for the production of bis(tertbutylimido)bis(dialkylamido)tungsten compounds according to one of the exemplary embodiments described above, R^{A} and R^{B} are independently selected from the group consisting of Me, Et, nPr, iPr, nBu, tBu, sBu, iBu, CH₂sBu, CH₂iBu, CH(Me)(iPr), CH(Me)(nPr), CH(Et)₂, C(Me)₂(Et), C₆H₁₁, CH₂C₆H₅ and C₆H₅. Exemplary compounds are [W(NtBu)₂(NMe₂)₂] and [W(NtBu)₂(NEtMe)₂].

In another embodiment of the bis(tertbutylimido)bis(dialkylamido)tungsten compounds according to the general formula [W(NtBu)₂(NR^{A}R^{B})₂] (I), obtainable by a method for the production of bis(tertbutylimido)bis(dialkylamido)tungsten compounds according to one of the exemplary embodiments described above, R is selected from the group consisting of 2-fluoroethyl, 2,2-dichloro-2-fluoroethyl, 2-chloroethyl, 2-bromoethyl, 2,2-dibromoethyl, 2,2,2-tribromoethyl, hexafluoroisoprophyl, (2,2-dichlorocyclopropyl)methyl and (2,2-dichloro-1-phenyl-cyclopropyl)methyl.

Owing to their purity, in particular the absence of lithium impurities, the compounds according to the general formula [W(NtBu)₂(NR^{A}R^{B})₂] (I) that can be produced with the claimed method are particularly well suited as precursors for the production of a high-quality tungsten layer or tungsten-containing layer on a surface of a substrate.

The object is also achieved by the use of a bis(tertbutylimido)bis(dialkylamido)tungsten compound according to the general formula

[W(NtBu)₂(NR^{A}R^{B})₂] (I),

wherein
R^{A} and R^{B} are independently selected from the group consisting of linear and branched alkyl radicals having 1 to 20 carbon atoms,
obtained according to a method for the production of bis(tertbutylimido)bis(dialkylamido)tungsten compounds according to one of the exemplary embodiments described above
   or
obtainable according to a method for the production of bis(tertbutylimido)bis(dialkylamido)tungsten compounds according to one of the exemplary embodiments described above for the production of a tungsten layer or a tungsten-containing layer on a surface of a substrate.

This is a method for the production of a tungsten layer or a tungsten-containing layer on a surface of a substrate

using a bis(tertbutylimido)bis(dialkylamido)tungsten compound according to the general formula [W(NtBu)₂(NR^{A}R^{B})₂] (I),
obtained according to a method for the production of bis(tertbutylimido)bis(dialkylamido)tungsten compounds according to one of the exemplary embodiments described above
   or
obtainable according to a method for the production of bis(tertbutylimido)bis(dialkylamido)tungsten compounds according to one of the exemplary embodiments described above, comprising the steps of:
   a) providing the bis(tertbutylimido)bis(dialkylamido)tungsten compound according to the general formula [W(NtBu)₂(NR^{A}R^{B})₂] (I),
   and
   b) depositing the tungsten layer or the tungsten-containing layer on the surface of the substrate.

The tungsten-containing layer may be, for example, a layer of WN, WON, WSi, WSiN or WO.

The term “layer” is synonymous with the expression “film” and does not make any statement regarding the layer thickness or the film thickness. Corundum foils or thin metallic foils can, for example, be used as the substrate. The substrate itself can be part of a component. The tungsten layer or the tungsten-containing layer can be deposited by means of a vapor deposition method, in particular by means of various ALD methods (atomic layer deposition) and CVD methods (chemical vapor deposition).

Due to their high purity, the bis(tertbutylimido)bis(dialkylamido)tungsten compounds used are particularly well suited as precursors for the production of high-quality tungsten layers and tungsten-containing layers on a surface of a substrate. In particular, due to the method used for their production, unlike the compounds obtainable by means of the known method, they are inherently free from lithium impurities which are disadvantageous for the coating process and thus for the performance of the coated substrates.

In one embodiment of the use of a bis(tertbutylimido)bis(dialkylamido)tungsten compound according to the general formula [W(NtBu)₂(NR^{A}R^{B})₂] (I), obtained or obtainable by a method for the production of bis(tertbutylimido)bis(dialkylamido)tungsten compounds according to one of the previously described exemplary embodiments, for the production of a tungsten layer or a tungsten-containing layer on a surface of a substrate or in one embodiment of the method for the production of a tungsten layer or a tungsten-containing layer on a surface of a substrate, the substrate is a wafer. The wafer may comprise silicon, silicon carbide, germanium, gallium arsenide, indium phosphide, a glass, such as SiO₂, and/or a plastic, such as silicone, or consist entirely of one or more such materials. The wafer can also have one or more wafer layers, each having one surface. The production of the tungsten layer or the tungsten-containing layer may be provided on the surface of one or more wafer layers.

The object is further achieved by bis(tertbutylimido)bis(dialkylamido)tungsten compounds according to the general formula

[W(NtBu)₂(NR^{A}R^{B})₂] (I),

wherein
R^{A} and R^{B} are independently selected from the group consisting of linear and branched alkyl radicals having 1 to 20 carbon atoms,
wherein
the bis(tertbutylimido)bis(dialkylamido)tungsten compounds [W(NtBu)₂(NMe₂)₂] and [W(NtBu)₂(NEtMe)₂], are excluded.

The bis(tertbutylimido)bis(dialkylamido)tungsten compounds according to the general formula [W(NtBu)₂(NR^{A}R^{B})₂] (I) can advantageously be produced particularly easily and economically in a two-stage synthesis. The compounds of the type [W(NtBu)₂(NR^{A}R^{B})₂] (I) can be produced reproducibly in high purity, even without any further distillative and/or sublimative purification. However, it is possible, for example, to provide transcondensation and/or distillation and/or sublimative purification. The bis(tertbutylimido)bis(dialkylamido)tungsten compounds according to the general formula [W(NtBu)₂(NR^{A}R^{B})₂] (I) meet the purity requirements of precursors for the production of high-quality substrates which have tungsten layers or tungsten-containing layers. In particular, they can be produced without the use of lithium-containing educts, such as lithium dimethylamide, and are thus obtainable free from lithium impurities. In addition, the bis(tertbutylimido)bis(dialkylamido) tungsten compounds can also be is produced on an industrial scale, wherein comparable yields and purity of the target compounds are achieved.

Owing to their purity, in particular the absence of lithium impurities, and the fact that they can be produced easily and economically on an industrial scale, compounds according to the general formula [W(NtBu)₂(NR^{A}R^{B})₂] (I) are particularly well suited as precursors for the production of a high-quality tungsten layer or tungsten-containing layer on a surface of a substrate.

The object is also achieved by the use of bis(tertbutylimido)bis(dialkylamido)tungsten compounds according to the general formula

[W(NtBu)₂(NR^{A}R^{B})₂] (I),

wherein
R^{A} and R^{B} are independently selected from the group consisting of linear and branched alkyl radicals having 1 to 20 carbon atoms,
for the production of a tungsten layer or a tungsten-containing layer on a surface of a substrate,
wherein the bis(tertbutylimido)bis(dialkylamido)tungsten compound [W(NtBu)₂(NMe₂)₂] is excluded,

The invention relates to a method for the production of a tungsten layer or a tungsten-containing layer on a surface of a substrate

using a bis(tertbutylimido)bis(dialkylamido)tungsten compound according to the general formula [W(NtBu)₂(NR^{A}R^{B})₂] (I), wherein
R^{A} and R^{B} are independently selected from the group consisting of linear and branched alkyl radicals having 1 to 20 carbon atoms,
comprising the steps of:
a) providing the bis(tertbutylimido)bis(dialkylamido)tungsten compound according to the general formula [W(NtBu)₂(NR^{A}R^{B})₂] (I)
and
b) depositing the tungsten layer or the tungsten-containing layer on the surface of the substrate.

The tungsten-containing layer may be, for example, a layer of WN, WON, WSi, WSiN or WO.

The term “layer” is synonymous with the expression “film” and does not make any statement regarding the layer thickness or the film thickness, Corundum foils or thin metallic foils can, for example, be used as the substrate.

The substrate itself can be part of a component. The tungsten layer or the tungsten-containing layer can be deposited by means of a vapor deposition method, in particular by means of various ALD methods (atomic layer deposition) and CVD methods (chemical vapor deposition).

Due to their high purity, the bis(tertbutylimido)bis(dialkylamido)tungsten compounds used are particularly well suited as precursors for the production of high-quality tungsten layers and tungsten-containing layers on a surface of a substrate. In particular, due to the method used for their production, unlike the compounds obtainable by means of the known method, they are inherently free from lithium impurities which are disadvantageous for the coating process and thus for the performance of the coated substrates.

In one embodiment of the use of a bis(tertbutylimido)bis(dialkylamido)tungsten compound according to the general formula [W(NtBu)₂(NR^{A}R^{B})₂] (I) for the production of a tungsten layer or a tungsten-containing layer on a surface of a substrate or in one embodiment of the method for the production of a tungsten layer or a tungsten-containing layer on a surface of a substrate, the substrate is a wafer. The wafer may comprise silicon, silicon carbide, germanium, gallium arsenide, indium phosphide, a glass, such as SiO₂, and/or a plastic, such as silicone, or consist entirely of one or more of said materials. The wafer can also have one or more wafer layers, each having one surface. The production of the tungsten layer or the tungsten-containing layer may be provided on the surface of one or more wafer layers.

The object is further achieved by a substrate which has a tungsten layer or a tungsten-containing layer on a surface,

wherein the tungsten layer of the tungsten-containing layer can be produced using a bis(tertbutylimido)bis(dialkylamido)tungsten compound according to the general formula [W(NtBu)₂(NR^{A}R^{B})₂] (I),
obtained or obtainable according to a method for the production of bis(tertbutylimido)bis(dialkylamido)tungsten compounds according to one of the exemplary embodiments described above,
wherein R^{A} and R^{B} are independently selected from the group consisting of linear and branched alkyl radicals having 1 to 20 carbon atoms.

Moreover, the object is further achieved by a substrate which has a tungsten layer or a tungsten-containing layer on a surface,

wherein the tungsten layer of the tungsten-containing layer can be produced using a bis(tertbutylimido)bis(dialkylamido)tungsten compound according to the general formula [W(NtBu)₂(NR^{A}R^{B})₂] (I),
wherein R^{A} and R^{B} are independently selected from the group consisting of linear and branched alkyl radicals having 1 to 20 carbon atoms,
wherein the bis(tertbutylimido)bis(dialkylamido)tungsten compound [W(NtBu)₂(NMe₂)₂] is excluded.

The tungsten-containing layer may be, for example, a layer of WN, WCN, WSi, WSiN or WO.

The term “layer” is synonymous with the expression “film” and does not make any statement regarding the layer thickness or the film thickness. Corundum foils or thin metallic foils can, for example, be used as the substrate. The substrate itself can be part of a component. The tungsten layer or the tungsten-containing layer can be deposited by means of a vapor deposition method, in particular by means of various ALD methods (atomic layer deposition) and CVD methods (chemical vapor deposition).

Owing to their high purity, the bis(tertbutylimido)bis(dialkylamido)tungsten compounds used are particularly well suited as precursors for the production of high-quality tungsten layers and tungsten-containing layers. In particular, due to the method used for their production, unlike the compounds obtainable by means of the known method, they are inherently free from lithium impurities which are disadvantageous for the coating process and thus for the performance of the coated substrates.

In one embodiment of the substrate, which has on a surface a tungsten layer or a tungsten-containing layer, wherein the tungsten layer or the tungsten-containing layer can be produced using a bis(tertbutylimido)bis(dialkylamido)tungsten compound according to the general formula [W(NtBu)₂(NR^{A}R^{B})₂] (I), obtained or obtainable, in particular, by a method for the production of bis(tertbutylimido)bis(dialkylamido)tungsten compounds according to one or more of the exemplary embodiments described above, the substrate is a wafer. The wafer may comprise silicon, silicon carbide, germanium, gallium arsenide, indium phosphide, a glass, such as SiO₂, and/or a plastic, such as silicone, or consist entirely of one or more of said materials. The wafer can also have one or more wafer layers, each having one surface. The production of the tungsten layer or the tungsten-containing layer may be provided on the surface of one or more wafer layers.

The object is further achieved by the use of a bis(tertbutylimido)bis(dialkylamido)tungsten compound according to the general formula [W(NtBu)₂(NR^{A}R^{B})₂] (I), obtained or obtainable by a method for the production of bis(tertbutylimido)bis(dialkylamido)tungsten compounds according to one of the previously described exemplary embodiments, for the production of an electronic component. In the context of the present invention, the term “electronic component” is also intended to mean “electronic part”.

This is a method for the production of an electronic component using a bis(tertbutylimido)bis(dialkylamido)tungsten compound according to the general formula [W(NtBu)₂(NR^{A}R^{B})₂] (I),

obtained or obtainable according to a method for the production of bis(tertbutylimido)bis(dialkylamido)tungsten compounds according to one of the exemplary embodiments described above,
wherein
R^{A} and R^{B} are independently selected from the group consisting of linear and branched alkyl radicals having 1 to 20 carbon atoms,
comprising the steps of:
a) providing the bis(tertbutylimido)bis(dialkylamido)tungsten compound according to the general formula [W(NtBu)₂(NR^{A}R^{B})₂] (I),
b) depositing a tungsten layer or a tungsten-containing layer on a surface of a substrate,
and
c) completing the electronic component.

The object is further achieved by a method for the production of an electronic component using a bis(tertbutylimido)bis(dialkylamido)tungsten compound according to the general formula [W(NtBu)₂(NR^{A}R^{B})₂] (I), using a bis(tertbutylimido)bis(dialkylamido)tungsten compound according to the general formula [W(NtBu)₂(NR^{A}R^{B})₂] (I),

wherein
R^{A} and R^{B} are independently selected from the group consisting of linear and branched alkyl radicals having 1 to 20 carbon atoms,
wherein the bis(tertbutylimido)bis(dialkylamido)tungsten compound [W(NtBu)₂(NMe₂)₂] is excluded,
comprising the steps of:
a) providing the bis(tertbutylimido)bis(dialkylamido)tungsten compound according to the general formula [W(NtBu)₂(NR^{A}R^{B})₂] (I) ,
b) depositing a tungsten layer or a tungsten-containing layer on a surface of a substrate,
and
c) completing the electronic component.

In the context of the present invention, the term “electronic component” is also intended to mean “electronic part”.

Owing to their purity, the bis(tertbutylimido)bis(dialkylamido)tungsten compounds used are particularly well suited as precursors for the production of high-quality substrates which have tungsten layers or tungsten-containing layers. Said substrates are used for the production of electronic components and electronic parts. In addition, bis(tertbutylimido)bis(dialkylamido)tungsten compounds used can be produced particularly easily and economically in good and reproducible yields and high purity by means of a two-stage synthesis described above. In particular, they can be produced lithium-free by means of the method claimed here. They are, therefore, suitable for use on an industrial scale.

With the claimed method, defined bis(tertbutylimido)bis(dialkylamido)tungsten compounds can be produced easily, economically and reproducibly in high purity and good yields. The compounds, which can be produced in a two-stage synthesis, already have a high purity after their isolation according to ¹H-NMR spectra. No complex purification of the respectively isolated raw product by fractionating distillation and/or sublimation is required for this purpose. However, transcondensation and/or distillation and/or sublimation and/or crystallization and/or recrystallization may be provided. Owing to their high purity, in particular the absence of lithium impurities and impurities due to inorganic salts, the compounds producible by the claimed method are suitable for use as precursors for the production of high-quality substrates which have tungsten layers or tungsten-containing layers. The compounds of the general formula [W(NtBu)₂(NR^{A}R^{B})₂] (I) may, because of their high purity, be used, for example, to produce high-quality contact materials, barrier layers, electrodes for thin film capacitors and field effect transistors, each consisting of or comprising, for example, tungsten nitride layers. In addition, the method claimed is characterized in that it can also be carried out on an industrial scale, with a comparable yield and purity of the target compounds. Overall, the claimed method is to be assessed as satisfactory from an ecological and economic point of view,

Other features, details, and advantages of the invention follow from the wording of the claims as well as from the following description of exemplary embodiments.

Process Specifications for the Synthesis of [W(NtBu)₂(NHtBu)₂] and [W(NtBu)₂(NMe₂)₂]

### Materials and Methods:

All reactions were carried out in a protective gas atmosphere. Work was carried out using conventional Schlenk techniques, with nitrogen or argon being used as protective gas. The corresponding vacuum rakes or Schlenk lines were connected to rotary vane pumps made by Vacuubrand. The educts, reagents and synthesized products were weighed and stored in glove boxes made by MBraun (model MB 150 8G-1 or Lab Master 130) under a nitrogen atmosphere.

The deuterated solvent C₆D₆ was dehydrated over a K/Na alloy, then condensed and stored over a molecular sieve.

All nuclear magnetic resonance spectroscopic measurements were performed in automated mode on an AV II 300 instrument or in manual mode on an AV III HD 250 or AV III HD 300 instrument. ¹H and ¹³C-NMR spectra were calibrated to the corresponding residual proton signal of the solvent as an internal standard: ¹H-NMR spectra: C₆D₆: 7.16 ppm (s); ¹³C-NMR spectra: C₆D₆: 128.0 ppm (tr). The chemical shifts are indicated in ppm and refer to the δ scale. All signals are provided with the following abbreviations according to their splitting pattern: s (singlet).

In substance, the measurements of infrared spectra were usually performed on an Alpha ATR-IR spectrometer made by Bruker. The absorption bands are indicated in wave number (cm⁻¹), and the intensity is described with the following abbreviations: w (weak), m (medium strong), st (strong), vst (very strong). The spectra were always normalized to the band with the highest intensity.

The elemental analyses were carried out on a vario MICRO cube combustion device made by Elementar. Sample preparation was carried out in a glove box flooded with nitrogen by weighing the substance in tin crucibles, which were cold-welded and stored in a protective gas atmosphere until measurement. The elements of hydrogen, carbon and nitrogen were determined by means of a combustion analysis, wherein the information is always given in mass percent.

All EI mass spectrometric investigations were performed on an AccuTOF GCv spectrometer made by Joel. Air-sensitive and moisture-sensitive samples were prepared in a glove box in crucibles and stored in a protective gas atmosphere until measurement. In the case of high-resolution spectra, the signal with the highest intensity of the isotope pattern is respectively indicated.

The thermogravimetric investigations were performed on a TGA/DSC 3+ STAR system made by Mettler Toledo. In the process, a coupled SDTA measurement was performed for each TGA. The sample was measured in an aluminum oxide, aluminum or sapphire crucible, depending on the method or state of aggregation. The sample was heated at a specific heating rate from 25° C. to the final temperature. The evaluation of the spectra obtained was carried out with STARe software made by Mettler Toledo.

### Exemplary Embodiment 1: Production of [W(NtBu)₂(NHtBu)₂]

The synthesis was carried out based on a specification of Nugent and Harlow. (W. A. Nugent, R. L. Harlow, Inorg. Chem. 1980, 19, 777-779)

tBuNH₂ (21.0 g, 287 mmol, 11.4 equiv.) was added to 350 mL n-hexane and WCl₆ (10.0 g, 25.2 mmol, 1.00 equiv.) was added in portions at room temperature. The reaction mixture turned slightly yellow while a colorless solid precipitated out. The reaction mixture was stirred for 72 h at room temperature.

The precipitated solid was filtered off and the solvent of the filtrate was removed in a fine vacuum (10⁻³ to 10⁻² mbar). The product was purified sublimatively at 65° C. in a fine vacuum (10⁻³ to 10⁻² mbar) and obtained as a pale yellow solid with a yield of 71% (8.28 g, 17.6 mmol).

Alternatively, the product can be crystallized from toluene at −24° C. However, the yield is then only 45-51%.

¹H-NMR (C₆D₆, 300 MHz, 300 K): δ/ppm=1.27 (s, 18 H, NCMe₃), 1.45 (s, 18 H, NHCMe₃), 5.22 (s, 2 H, NHCMe₃); ¹³C-NMR (C₆D₆, 75 MHz, 300 K): δ/ppm=33.7 (NCMe₃), 33.8 (NHCMe₃), 53.3 (NHCMe₃), 66.0 (NCMe₃); TGA (T_{S}=25° C., T_{E}=900° C., 10° C./min): Stages; 1, 3% degradation: 125.3° C., T_{MA}: 195.7° C., total mass degradation: 95.0%; SDTA: T_{M(Onset)}: 85.3° C., T_{M(max)}: 90.0° C., T_{D(Onset)}: 137.3° C., T_{D(max.)}: 150.8° C.

### Exemplary Embodiment 2: Production of [W(NtBu)₂(Me₂)₂]

[W(NtBu)₂(NHtBu)₂] (250 mg, 0.53 mmol, 1,00 equiv.) was added, frozen in liquid nitrogen and HNMe₂ (5.13 g, 114 mmol, 215 equiv), which had been dried beforehand according to standard methods, condensed. The reaction mixture was slowly heated to −20° C. until [W(NtBu)₂(NHtBu)₂] dissolved. The pale yellow solution was heated to −15° C. and stirred for 2 h. The orange reaction mixture was brought to room temperature, wherein excess HNMe₂ evaporated. Residues of HNMe₂ and tBuNH₂ produced were removed in a fine vacuum (10⁻³ to 10¹ mbar). The product was obtained in the form of an orange liquid with a yield of 93% (206 mg, 0.50 mmol).

¹H-NMR (C₆D₆, 300 MHz, 300 K): δ/ppm=1.41 (s, 18 H, CMe₃), 3.51 (s, 12 H, NMe₂); ¹³C-NMR (C₆D₆, 75 MHz, 300 K); δ/ppm=34.1 (CMe₃), 53.8 (NMe₂), 66.2 (CMe₃); IR: \tilde{ν}/cm⁻¹=2965 (m), 2919 (m), 2896 (m), 2857 (m), 2821 (m), 2776 (m), 1450 (m), 1421 (w), 1354 (m), 1288 (m), 1240 (vst), 1212 (st), 1159 (w), 1142 (w), 1125 ('N), 1054 (w), 1024 (w), 975 (st), 958 (vst), 806 (w), 780 (w), 696 (w), 636 (w), 561 (st), 476 (w); Elementary analysis for Cl₂H₃₀N₄W: calculated; C: 34.79%, H: 7.30%, N: 13.53%, found: C: 33.21%, H: 6.74%, N: 14.89%; HR-EI-MS: calculated for C₁₂H₃₀N₄W: 414.1979 m/z, found: 414.1964 m/z; TGA (T_{S}=25° C., T_{E}=600° C., 10° C./min): Stages: 1, 3% degradation: 120.7° C., T_{MA}: 185.2° C., total mass degradation: 97.3%; SDTA: T_{D(Onset)}: 150.3° C., T_{D(max.)}: 186.9° C.

The invention is not limited to one of the embodiments described above but may be modified in many ways.

It can be seen that the invention relates to a two-stage synthesis for the production of bis(tertbutylimido)bis(dialkylamido)tungsten compounds according to the general formula [W(NtBu)₂(NR^{A}R^{B})₂] (I), starting from [W(NtBu)₂(NHtBu)₂]. The invention further relates to compounds according to the general formula [W(NtBu)₂(NR^{A}R^{B})₂] (I), obtainable according to the claimed method, compounds according to the general formula [W(NtBu)₂(NR^{A}R^{B})₂] (I), with the exception of [W(NtBu)₂(NMe₂)₂] and [W(NtBu)₂(NMe₂)₂], the use of a compound [W(NtBu)₂(NR^{A}R^{B})₂] (I) and a substrate which, on a surface, has a tungsten layer or a tungsten-containing layer.

With the described method, defined bis(tertbutylimido)bis(dialkylamido)tungsten compounds of the type [W(NtBu)₂(NR^{A}R^{B})₂] (I) can be produced easily, efficiently, economically and reproducibly in high purity and good yields. The method can also be carried out on an industrial scale. Already after their isolation, without complex purification, the compounds do not have any NMR spectroscopically detectable impurities. Owing to their high purity, in particular the absence of lithium impurities, they are suitable as precursors for the production of high-quality substrates which have tungsten layers or layers containing tungsten. For example, they are suitable for the production of high-quality contact materials or barrier layers, including, for example, tungsten nitride.

All features and advantages resulting from the claims, the description and the figures, including constructive details, spatial arrangements and method steps, can be essential to the invention, both in themselves and in the most diverse combinations.

1. Method for the production of bis(tertbutylimido)bis(dialkylamido)tungsten compounds
according to the general formula
[W(NtBu)₂(NR^{A}R^{B})₂] (I),
wherein
R^{A} and R^{B} are independently selected from the group consisting of linear and branched alkyl radicals having 1 to 20 carbon atoms,
comprising the following steps:
a) provision of [W(NtBu)₂(NHtBu)₂]
and
b) reaction of [W(NtBu)₂(NHtBu)₂] from step a) with an amine according to the general formula HNR^{A}R^{B} in a solvent M_{U},
wherein
R^{A} and R^{B} are independently selected from the group consisting of linear and branched alkyl radicals having 1 to 20 carbon atoms,
and
a molar ratio [W(NtBu)₂(NHtBu)₂]:HNR^{A}R^{B} is <1:2.

2. Method according to claim 1, wherein the provision of [W(NtBu)₂(NHtBu)₂] comprises a reaction of WCl₆ with tBuNH₂ in the presence of an auxiliary base in an aprotic solvent M_{A},
wherein a molar ratio WCl₆:tBuNH₂ is ≤1:4.

3. Method according to claim 2, wherein the auxiliary base comprises or is tBuNH₂.

4. Method according to claim 2, wherein the aprotic solvent M_{A} is selected from the group consisting of hydrocarbons, benzene and benzene derivatives.

5. Method according to claim 2, wherein the aprotic solvent M_{A} is selected from the group consisting of n-pentane, n-hexane, n-heptane, n-octane, n-nonane, n-decane, n-undecane, n-dodecane, cyclopentane, cyclohexane, cycloheptane, 1-pentene, 1-hexene, 1-heptene, 1-octene, 1-nonene, 1-decene, 1-undecene, 1-dodecene, cyclohexene, benzene, toluene, xylene and isomers thereof.

6. Method according to claim 2, wherein the reaction of WCl₆ with tBuNH₂ in the presence of the auxiliary base in the aprotic solvent M_{A} comprises the following steps:
i) providing a solution of tBuNH₂ in the aprotic solvent M_{A},
ii) adding the auxiliary base,
iii) adding WCl₆,
wherein during the addition and/or after the addition of WCl₆, a reaction of WCl₆ with tBuNH₂ takes place.

7. Method according to claim 2, wherein the reaction of WCl₆ with tBuNH₂ in the presence of the auxiliary base in the aprotic solvent M_{A} is carried out at a temperature T_{U}, wherein the temperature T_{U} is between −30° C. and 100° C.

8. Method according to claim 2, wherein a filtration step is carried out prior to the reaction of [W(NtBu)₂(NHtBu)₂] in step b).

9. Method according to claim 1, wherein [W(NtBu)₂(NHtBu)₂] is isolated prior to the reaction of [W(NtBu)₂(NHtBu)₂] in step b).

10. Method according to claim 1, wherein in step b) the molar ratio [W(NtBu)₂(NHtBu)₂]:HNR^{A}R^{B} is ≤1:4.

11. Method according to claim 1, wherein the solvent M_{U} comprises an aprotic solvent.

12. Method according to claim 2, wherein the solvent M_{U} is miscible with or identical to the aprotic solvent M_{A}.

13. Method according to claim 11, wherein the aprotic solvent M_{A}, which comprises the solvent M_{U}, is selected from the group consisting of hydrocarbons, benzene and benzene derivatives.

14. Method according to claim 11, wherein the aprotic solvent, which comprises the solvent M_{U}, is selected from the group consisting of n-pentane, n-hexane, n-heptane, n-octane, n-nonane, n-decane, n-undecane, n-dodecane, cyclopentane, cyclohexane, cycloheptane, 1-pentene, 1-hexene, 1-heptene, 1-octene, 1-nonene, 1-decene, 1-undecene, 1-dodecene, cyclohexene, benzene, toluene, xylene and isomers thereof.

15. Method according to claim 1, wherein the solvent M_{U} comprises a reactive solvent.

16. Method according to claim 15, wherein the reactive solvent comprises the amine HNR^{A} R^{B}.

17. Method according to claim 1, wherein step b) is carried out at a temperature T_{R} and/or a pressure p_{R}, wherein at the temperature T_{R} and/or the pressure p_{R}, at least a portion of a molar fraction of the amine NHR^{A}R^{B} is present in liquid or dissolved form.

18. Method according to claim 1, wherein in step b) the reaction of [W(NtBu)₂(NHtBu)₂] from step a) with the amine HNR^{A}R^{B} comprises the following steps:
i) providing [W(NtBu)₂(NHtBu)₂]
as a solid
or
as a solution or suspension in the solvent M_{U},
and
ii) adding the amine HNR^{A}R^{B},
wherein, during and/or after the addition of the amine HNR^{A}R^{B}, a reaction of [W(NtBu)₂(NHtBu)₂] with the amine HNR^{A}R^{B} takes place.

19. Method according to claim 18, wherein the amine HNR^{A}R^{B} is added
as a gas or liquid
or
dissolved in the solvent M_{U}.

20. Method according to claim 18, wherein a temperature T_{C} is between −60° C. and 50° C. during the addition and/or after the addition of the amine HNR^{A}R^{B}.

21. Method according to claim 1, wherein after step b) isolation of [W(NtBu)₂(NR^{A}R^{B})₂] (I) takes place.

22. Method for the production of a tungsten layer or a tungsten-containing layer on a surface of a substrate
using a bis(tertbutylimido)bis(dialkylamido)tungsten compound according to the general formula [W(NtBu)₂(NR^{A}R^{B})₂] (I), comprising the steps of:
a) providing the bis(tertbutylimido)bis(dialkylamido)tungsten compound according to the general formula [W(NtBu)₂(NR^{A}R^{B})₂] (I)) by a method according to claim 1,
and
b) depositing the tungsten layer or the tungsten-containing layer on the surface of the substrate.

23. Method for the production of a tungsten layer or a tungsten-containing layer on a surface of a substrate
using a bis(tertbutylimido)bis(dialkylamido)tungsten compound according to the general formula [W(NtBu)₂(NR^{A}R^{B})₂] (I),
wherein
R^{A} and R^{B} are independently selected from the group consisting of linear and branched alkyl radicals having 1 to 20 carbon atoms,
and
the bis(tertbutylimido)bis(dialkylamido)tungsten compound [W(NtBu)₂(NMe₂)₂] is excluded,
comprising the steps of:
a) providing the bis(tertbutylimido)bis(dialkylamido)tungsten compound according to the general formula [W(NtBu)₂(NR^{A}R^{B})₂] (I)) by a method according to claim 1,
and
b) depositing the tungsten layer or the tungsten-containing layer on the surface of the substrate.

24. Method for the production of an electronic component,
using a bis(tertbutylimido)bis(dialkylamido)tungsten compound according to the general formula [W(NtBu)₂(NR^{A}R^{B})₂] (I) , comprising the steps of:
a) providing the bis(tertbutylimido)bis(dialkylamido)tungsten compound according to the general formula [W(NtBu)₂(NR^{A}R^{B})₂] (I) by a method according to claim 1,
b) depositing a tungsten layer or a tungsten-containing layer on a surface of a substrate,
and
c) completing the electronic component.

25. Method according to claim 22, wherein a tungsten layer or a tungsten-containing layer is deposited by CVD (chemical vapor deposition) or ALD (atomic layer deposition).
